(19) United States
(12) Patent Application Publication
(10) Pub. No.: US 2023/0207169 A1
(43) Pub. Date: Jun. 29, 2023

(54) Ferromagnetic Metal-Ferrite Composites for High Frequency Inductor Applications

(71) Applicant: Northeastern University, Boston, MA (US)

(72) Inventors: Parisa ANDALIB, Malden, MA (US); Vincent HARRIS, Boston, MA (US)

(21) Appl. No.: 18/008,323

(22) PCT Filed: Jun. 15, 2021
(86) PCT No.: PCT/US2021/037519

§ 371 Date: Dec. 5, 2022

Related U.S. Application Data
(60) Provisional application No. 63/039,370, filed on Jun. 15, 2020.

(51) Int. Cl. H01F 1/34; H01F 1/26

(52) U.S. Cl. CPC H01F 1/344; H01F 1/26; H01F 2017/048

(57) ABSTRACT

Composite materials containing ferrite particles and ferromagnetic metallic particles are described for high capacity, low loss, high frequency inductor applications. The materials allow exceptional performance at frequencies from 10 kHz to above 500 MHz.

### CROSS-REFERENCE TO RELATED APPLICATIONS

This application claims priority to U.S. Provisional Application No. 63/039,370, filed 15 Jun. 2020, which is incorporated by reference herein in its entirety.

### BACKGROUND

Advances in recent years have completely redefined data transfer technologies with respect to finance, communication, and security. A major advance is the technological and market influence of the 5G (and soon to be 6G) revolution. Unfortunately, the inductance components involved in these technologies are principally limited by today's materials in terms of low permeability and efficiency up to a few MHz. To meet 5G requirements and further performance demands, new materials are required to resolve existing shortcomings of current state of the art solutions to energy conversion, conditioning, and storage in the form of inductor components.

### SUMMARY

The present technology provides composite materials for use in inductors. The materials offer core loss suppression and combine ferromagnetic metal and ferrite materials. In particular, the composites can be utilized for high frequency inductor applications with exceptional performance at frequencies from 10 kHz up to and beyond 500 MHz.

One aspect of the technology is a composite material comprising ferromagnetic metallic particles, resistive magnetic particles, and optionally a dielectric material or binder in which the particles are embedded. Either the ferromagnetic metallic particles or the resistive magnetic particles is present in the form of core particles as the main constituent, and the other particle type is present in the form of coating particles, which at least in part coat the core particles and form a minor constituent.

Another aspect of the technology is an electronic device or component containing the composite material described above. The device or component can be, for example, a transformer, an inductor, a power supply, a power inverter, a power converter, an inductor, a transmit and receive module, an electronically scanned phased array system, an electronic warfare system, an electromagnetic interference (EMI) suppressor or absorber, and a communication device having a switch-mode power supply conditioning component.

Yet another aspect of the technology is a method of fabricating a composite material as described above. The method includes the steps of: (a) providing a plurality of core particles and a plurality of coating particles, wherein the core particles comprise ferromagnetic metallic particles and the coating particle-s comprise resistive magnetic particles, or wherein the core particles comprise ferromagnetic metallic particles and the coating particles comprise ferromagnetic metallic particles; (b) mixing said core particles and said coating particles; (c) heating and applying pressure to the mixture from (b) to consolidate and densify the particles; and optionally (d) annealing the product of (c).

The present technology can be further summarized by the following list of features.

1. A composite material comprising (i) ferromagnetic metallic particles, (ii) resistive magnetic particles, and optionally (iii) a dielectric material or binder in which the particles of (i) and (ii) are embedded; wherein either (i) or (ii) is present in the form of core particles and the other of (i) and (ii) is present in the form of coating particles which at least in part coat the core particles.
2. The composite material of claim 1, wherein the core particles comprise said ferromagnetic metallic particles and the coating particles comprise said resistive magnetic particles.
3. The composite material of claim 1, wherein the core particles comprise said resistive magnetic particles and the coating particles comprise said ferromagnetic metallic particles.
4. The composite material of any of the preceding claims, wherein a first portion of the coating particles is bound to the core particles and a second portion of the coating particles is embedded in the dielectric material.
5. The composite material of any of claims 1-3, wherein essentially all of the coating particles are bound to the core particles.
6. The composite material of any of the preceding claims, wherein the core particles have a form selected from spheroids, platelets, and fibers, the spheroids having an aspect ratio (longest dimension to thickness) from about 1:1 to about 10:1, the platelets having an aspect ratio from about 10:1 to about 200:1, and the fibers having an aspect ratio from about 200:1 to about 1000000:1 or greater.
7. The composite material of any of the preceding claims, wherein the core particles have an average particle size from about 50 nm to about 500 micrometers.
8. The composite material of any of the preceding claims, wherein the coating particles have an average particle size from about 5 nm to about 100 micrometers.
9. The composite material of any of the preceding claims, wherein the ferromagnetic metallic particles have an electrical resistivity from about 20 microOhm-cm to about 500 microOhm-cm.
10. The composite material of any of the preceding claims, wherein the resistive magnetic particles have an electrical resistivity from about 10⁸ Ohm-cm to about 10¹² Ohm-cm.
11. The composite material of any of the preceding claims, wherein the ferromagnetic metallic particles comprise a material selected from the group consisting of FeSi silicon steels, FeNi permalloy steels, FeCo permendur steels, (Fe and/or Co and/or Ni)(B and/or Si and/or Zr)(Cu and/or Nb) nanocrystalline alloys, (Fe and/or Co and/or Ni)(B and/or Si and/or P) metallic glasses, and combinations thereof.
12. The composite material of any of the preceding claims, wherein the resistive magnetic particles comprise a material selected from the group consisting of: (i) spinel ferrites of formula [Me₁,Me₂]ₓfe₂₋ₓO₄, wherein Me₁ and Me₂ are selected from Ni, Mn, Zn, Cu, Fe, Co, Mg, Cr, and combinations thereof; (ii) garnet ferrites of formula [Y(Me₁)]₃Fe₅O₁₂, wherein Me₁ is selected from elements of the lanthanide series; and (iii) hexaferrite phases of the M-type [BaMe₁](FeMe₂)₁₂O₁₉, wherein Me₁ is selected from Sr, Mo, Ir, Hf, and elements of the lanthanide series, and Me₂ is selected from Co, Ni, Zn, Ti, Zr, Al, Ga, Sn, and combinations thereof.
13. The composite material of any of the preceding claims, wherein the resistive magnetic particles comprise a crystal structure selected from the group consisting of spinel-type, garnet-type, hexaferrite-type, and combinations thereof.
14. The composite material of any of the preceding claims, wherein the coating particles are present in an amount of greater than 0.01 wt-% and less than 2 wt-% based on the weight of the core particles as 100%.
15. The composite material of any of the preceding claims, wherein the material comprises said dielectric material or said binder.
16. The composite material of any of the preceding claims, wherein the material provides a reduction in core loss of at least about 60%, at least about 70%, or at least about 80% compared to a conventional ferromagnetic core when used in an inductor at any frequency from 10 kHz to 5 MHz, or from 10 kHz to 10 MHz, or from 10 kHz to 50 MHz, or from 10 kHz to 100 MHz.
17. An electronic device or component comprising the composite material of any of the preceding claims.
18. Use of the composite material of any of claims 1-16 or the electronic device or component of claim 17 in a device selected from the group consisting of a transformer, an electronic device, an inductor, a power supply, a power inverter, a power converter, an inductor, a transmit and receive module, an electronically scanned phased array system, an electronic warfare system, an EMI suppressor or absorber, and a communication device having a switch-mode power supply conditioning component.
19. A method of fabricating a composite material, the material comprising a plurality of core particles, each core particle coated with a plurality of coating particles, the method comprising the steps of:

(a) providing a plurality of core particles and a plurality of coating particles, wherein the core particles comprise ferromagnetic metallic particles and the coating particle-s comprise resistive magnetic particles, or wherein the core particles comprise ferromagnetic metallic particles and the coating particles comprise ferromagnetic metallic particles;

(b) mixing said core particles and said coating particles;

(c) heating and applying pressure to the mixture from (b) to consolidate and densify the particles; and optionally

(d) annealing the product of (c).

20. The method of claim 19, further comprising forming the mixture from (b) into a desired shape prior to or during (c).
21. The method of claim 19 or 20, wherein the core particles have a form selected from spheroids, platelets, and fibers, the spheroids having an aspect ratio (longest dimension to thickness) from about 1:1 to about 10:1, the platelets having an aspect ratio from about 10:1 to about 200:1, and the fibers having an aspect ratio from about 200:1 to about 1000000:1 or greater.
22. The method of claim 21, wherein the provided core particles are spheroids and the method further comprises deforming the core particles to increase their aspect ratio to a range from about 10:1 to about 200:1.
23. The method of claim 22, wherein the deforming comprises subjecting the provided core particles to ball milling.
24. The method of any of claims 19-23, wherein the core particles have an average particle size from about 50 nm to about 500 micrometers.
25. The method of any of claims 19-24, wherein the coating particles have an average particle size from about 5 nm to about 100 micrometers.
26. The method of any of claims 19-25, wherein the ferromagnetic metallic particles have an electrical resistivity from about 20 microOhm-cm to about 500 microOhm-cm.
27. The method of any of claims 19-26, wherein the resistive magnetic particles have an electrical resistivity from about 10⁸ Ohm-cm to about 10¹² Ohm-cm.
28. The method of any of claims 19-27, wherein the ferromagnetic metallic particles comprise a material selected from the group consisting of FeSi silicon steels, FeNi permalloy steels, FeCo permendur steels, (Fe and/or Co and/or Ni)(B and/or Si and/or Zr)(Cu and/or Nb) nanocrystalline alloys, (Fe and/or Co and/or Ni)(B and/or Si and/or P) metallic glasses, and combinations thereof.
29. The method of any of claims 19-28, wherein the resistive magnetic particles comprise a material selected from the group consisting of: (i) spinel ferrites of formula [Me₁,Me₂]ₓFe₂₋ₓO₄, wherein Me₁ and Me₂ are selected from Ni, Mn, Zn, Cu, Fe, Co, Mg, Cr, and combinations thereof; (ii) garnet ferrites of formula [Y(Me₁)]₃Fe₅O₁₂, wherein Me₁ is selected from elements of the lanthanide series; and (iii) hexaferrite phases of the M-type [BaMe₁](FeMe₂)₁₂O₁₉, wherein Me₁ is selected from Sr, Mo, Ir, Hf, and elements of the lanthanide series, and Me₂ is selected from Co, Ni, Zn, Ti, Zr, Al, Ga, Sn, and combinations thereof.
30. The method of any of claims 19-29, wherein the resistive magnetic particles comprise a crystal structure selected from the group consisting of spinel-type, garnet-type, hexaferrite-type, and combinations thereof.
31. The method of any of claims 19-30, wherein the coating particles are present in an amount of greater than 0.01 wt-% and less than 2 wt-% based on the weight of the core particles as 100%.
32. The method of any of claims 19-31, wherein in the formed composite material the coating particles cover from 10 to 100 percent of the surface of the core particles.
33. The method of any of claims 19-32, further comprising providing a dielectric material or binder material in (a) and mixing the dielectric or binder material with the core particles and coating particles in (b).
34. The method of claim 33, wherein in the formed composite material the dielectric material or binder material fills gaps between coated core particles, and wherein the dielectric material or binder material comprises unbound coating particles.
35. The method of claim 33, wherein in the formed composite material the dielectric material or binder material fills gaps between coated core particles, and wherein the dielectric material or binder material is essentially devoid of unbound coating particles.
36. A composite material fabricated by the method of any of claims 19-35.
37. An electronic device comprising the composite material of claim 36.

As used herein, the term “about” refers to a range of within plus or minus 10%, 5%, 1%, or 0.5% of the stated value.

As used herein, “consisting essentially of” allows the inclusion of materials or steps that do not materially affect the basic and novel characteristics of the claim. Any recitation herein of the term “comprising”, particularly in a description of components of a composition or in a description of elements of a device, can be exchanged with the alternative expression “consisting of” or “consisting essentially of”.

### BRIEF DESCRIPTION OF THE DRAWINGS

FIG. 1 depicts a composite material containing ferrite platelets with ferromagnetic metal particles coating the platelets and present as inter-particulates. The binder or host dielectric material is optional.

FIG. 2 depicts a composite material containing ferrite platelets decorated with ferromagnetic metal particles.

FIG. 3 depicts a composite material containing ferrite spheroids decorated with ferromagnetic metal particles.

FIG. 4A depicts a composite material containing ferromagnetic metal platelets with ferrite particles coating the platelets and present as inter-particulates. The binder or host dielectric material is optional. FIG. 4B shows a flow chart of a process for fabricating a composite material containing ferromagnetic metal core particles, platelets, or fibers with ferrite particles coating the core particles.

FIG. 5 depicts a composite material containing ferromagnetic metal platelets decorated with ferrite particles.

FIG. 6 depicts a composite material containing ferromagnetic metal spheroids decorated with ferrite particles.

FIG. 7 shows an SEM image of nanoparticles adhering to the surface of spherical ferromagnetic metallic particles of FeSiP-based particles with larger particulate coverage; the inset is a lower magnification view.

FIG. 8 shows an SEM Image of nanoparticles adhering to the surface of spherical ferromagnetic metallic particles of FeSiP-based particles with smaller particulate coverage; the inset is a lower magnification view.

FIG. 9 shows an SEM image of flake-like particles (platelets) made from the spherical particles of FIG. 7 using mechanical deformation by ball milling.

FIG. 10 shows a plot of percent change in permeability (%) v. frequency (MHz) caused by modification with YIG vs. alumina nanoparticles.

FIG. 11 shows a plot of percent change in imaginary permeability (%) v. frequency (MHz) caused by modification with YIG vs. alumina nanoparticles.

FIG. 12 shows a plot of percent change in magnetic loss tangent (%) v. frequency (MHz) caused by modification with YIG vs. alumina nanoparticles.

FIG. 13 shows a plot of percent change in magnetic loss tangent (%) v. frequency (MHz) for YIG coated metallic flakes.

FIG. 14 shows a schematic representation of an example of a fabrication process for making soft magnetic composite material of the present technology.

FIG. 15 shows real (μ′) and imaginary (μ″) components as frequency dependence of complex permeability.

FIG. 16 shows the maximum quality factor (Qmax) and corresponding frequency for sintered composites containing FeCuNbSiB@NiZn-ferrite core-shell particles x=1.0 wt. % (present technology) with comparison to reference samples in the literature.

### DETAILED DESCRIPTION

The present technology provides composite materials for high frequency inductor, high power applications. The materials are ferromagnetic metal-ferrite composites and provide core loss suppression with sustained soft magnetic properties. For example, the technology allows operation with exceptional performance at frequencies from 10 kHz up to and beyond 500 MHz, which no other existing technology can provide. Existing limited technologies are tapped out at 10 MHz for high power inductor core applications. The technology can provide very high frequency, high performance inductor cores needed for next generation power inverters/converters, filters, EMI suppressors, absorbers, and many other applications. The cost of manufacturing and processing is not more expensive, or is less expensive, than existing technologies.

The materials include 2 or 3 component composites including 1) highly resistive magnetic ferrite particles, 2) ferromagnetic metallic particles, and 3) an optional host dielectric or binder.

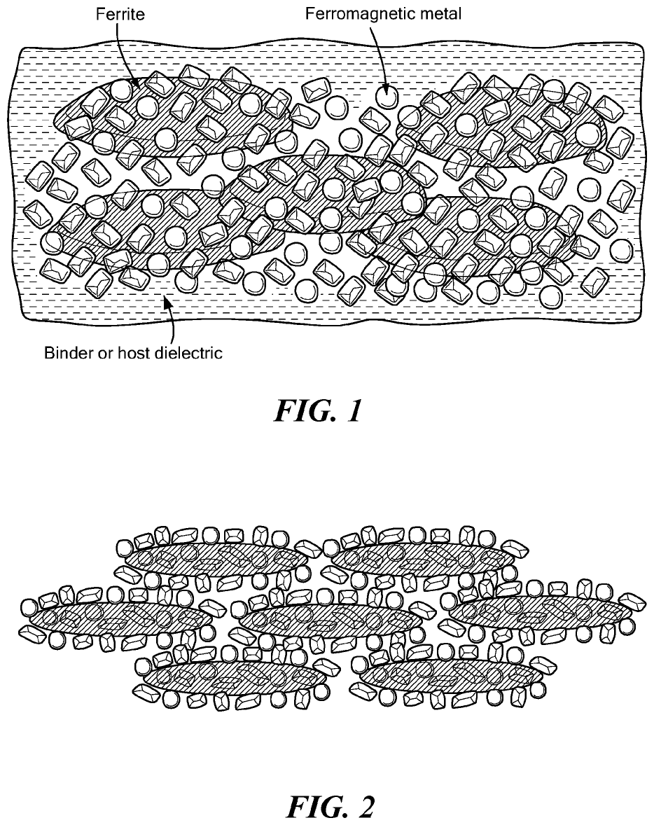

The electrically resistive magnetic particles can contain insulating magnetic oxides of the ferrite type (ferrite particles), and can be used as either a coating for metallic (FMP) core particles and optionally as an inter-particulate constituent, or as the major constituent particle (core particles). An example in the form of ferrite platelets coated with ferromagnetic metal particles, and having the ferromagnetic metal particles additionally present as particles between the core particles, is depicted in FIG. 1.

The ferromagnetic metallic particles (FMPs) can take the form of high permeable high magnetic moment alloys that may be crystalline (FeSi-based, FeNi-based, FeCo-based, etc.), nanocrystalline (similar to nanoperm or finemet and related alloys, e.g., FeCoNiNbCuSiB, FeCoNiNbZrCuSiB), or glassy or amorphous structures (similar to the metglas products, e.g., FeCoNiBSiP).

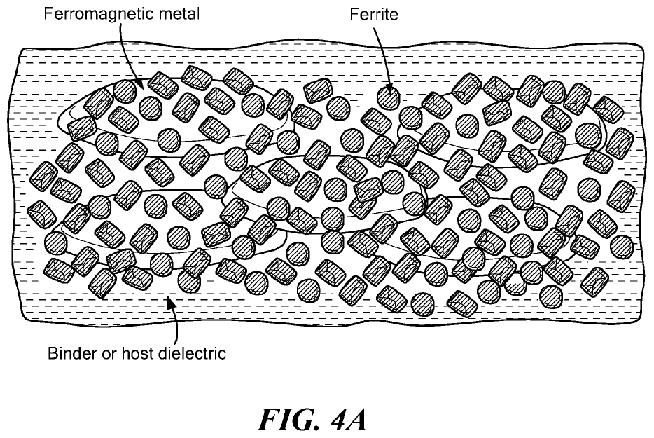

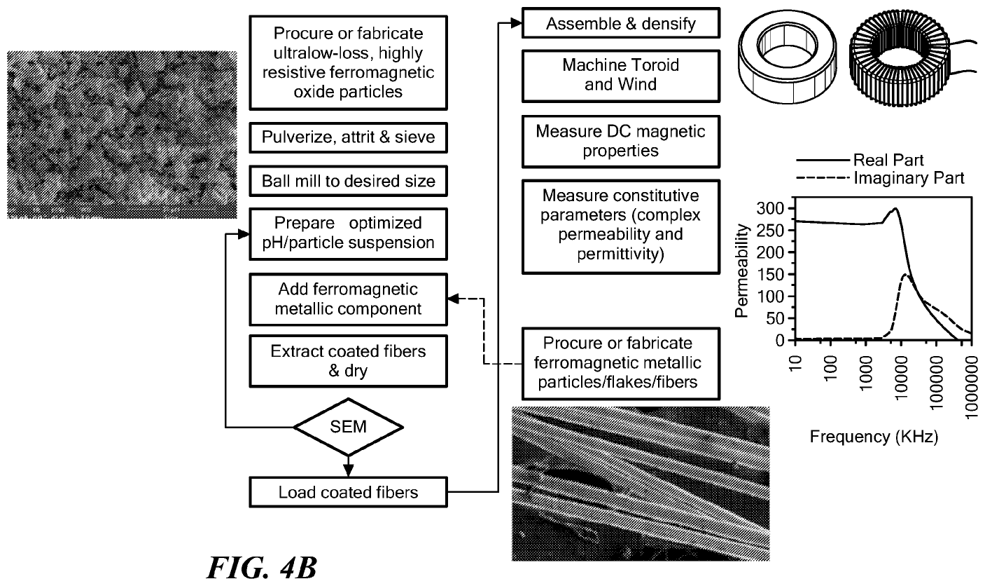

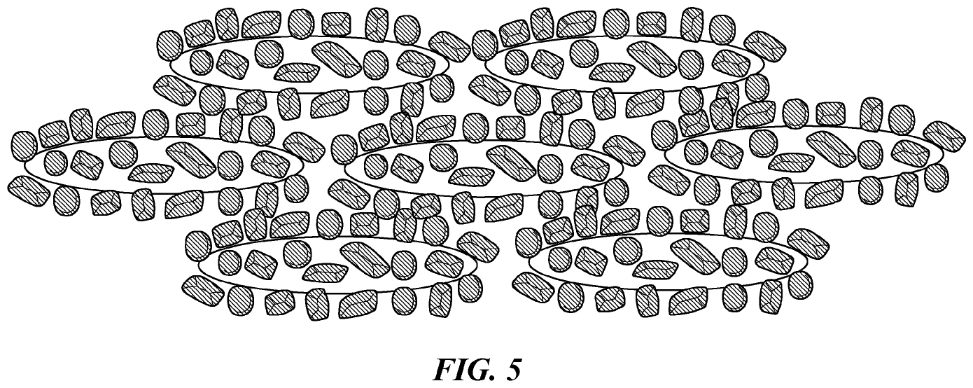

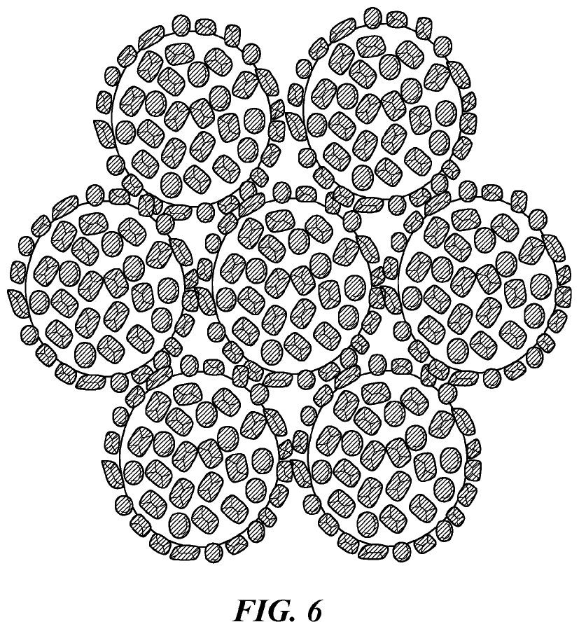

In a preferred embodiment, the coating particles are ferrite nanoparticles or microparticles that assemble on the surface of the larger core FMPs to disrupt eddy currents, thereby reducing total core losses (FIGS. 4A, 5, 6). In this role, some fraction of ferrite particles also can act as an inter-particulate constituent (IPC), residing between ferromagnetic metallic particles. If an optional dielectric or binder is used, the ferrite particles will partially or entirely coat the FMPs and also be suspended within the binder or host dielectric (FIG. 4A). In an alternative embodiment, the ferrite particles can replace the FMP as the main constituent (core particles), whereupon the FMP would serve as the surface coating and IPC as shown in FIG. 1.

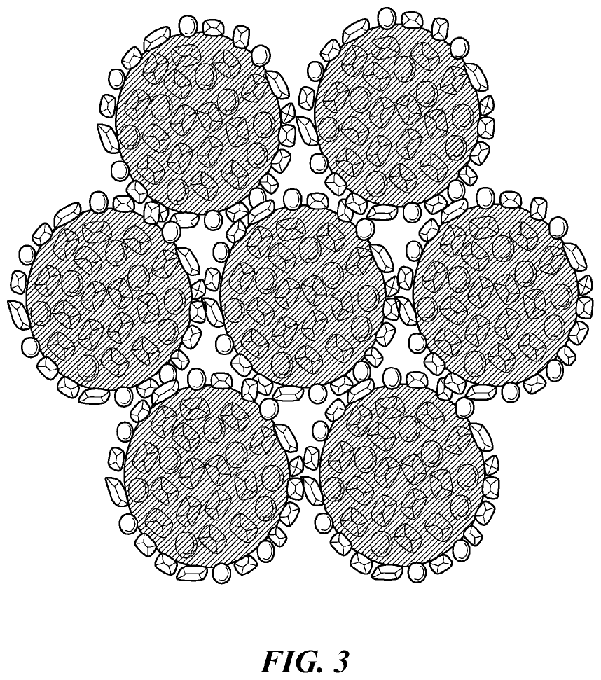

Similar to the role described for the ferrite particles, as a coating, the FMPs assemble on ferrite to improve permeability, magnetization, and Curie temperature. In this role, some fraction of the FMPs also acts as IPC residing between the ferrite particles (FIGS. 1-3). If an optional binder is used, the FMPs would coat the ferrites and also be suspended with the binder. As discussed above, the FMPs can replace the ferrite as the main constituent whereupon the ferrite would serve as the surface coating and IPC (FIGS. 4-6).

The third component, which is optional, is a host dielectric such as a thermoset or other polymer or plastic material, or a simple binder, depending upon the desired higher functionality. This material is used to bind the particles in an insulating matrix at high density while preventing electrical transmission between particles by separation of the particles, and optionally to stabilize the shape of the material. In the schematic illustrations of composite arrangements shown in FIGS. 1-6, the particle sizes and proportions are depicted schematically and do not represent true scales.

Composites of these constructs are shown not to sacrifice soft magnetic high frequency performance by: 1) disrupting electrical paths that give rise to eddy current losses thereby reducing cores' losses; 2) because both principle constituents (ferrite and FMP) are magnetic, long range magnetic interactions are maintained allowing for sustained high levels of magnetization, permeability, and Curie temperature; 3) adjusting the cutoff frequency of the ferromagnetic metal-ferrite composite to capture a wider spectral range of power density by increasing the AC resistivity and spin resonance frequency of the composite.

These composites, when used as inductor cores, lead to reduced core losses for high operating frequency operations. They maintain high permeability and high saturation magnetization, providing high efficiency with small form factors at very high frequencies.

In Table 1, example components of ferromagnetic metallic-ferrite composites for inductors are presented. The ceramic components can be ferrites of either spinel (NiZn-ferrite), garnet (YIG), or hexaferrite (BaM) phase, and the metal can be a ferromagnetic metallic glass. However, even though Table 1 lists only metallic glasses, the technology includes other ferromagnetic metallic particles such as crystalline (FeSi-based, FeNi-based, FeCo-based, etc.), nanocrystalline (similar to nanoperm or finemet and related alloys, e.g., FeCoNiNbCuSiB, FeCoNiNbZrCuSiB) in addition to the glassy structures (amorphous, similar to the metglas products, e.g., FeCoNiBSiP). As can be seen in Table 1 these components each provide valuable soft magnetic properties in their own right.

TABLE 1
Properties of Ferromagnetic Metallic-Ferrite Composite Constituents.
Example constituent materials of the proposed ferromagnetic
metallic-ferrite nanocomposite

| Component 1-Ferrite | | | | Component 2-Ferromagnetic | |
|---|---|---|---|---|---|
| | YIG | NiZn-ferrite | Hexaferrite | Metallic Glass | |
| ρ (Ω-cm) | 10¹⁰⁻¹² | 10⁸ | 10⁸ | ρ (μΩ-cm) | 140 |
| μ | 60 (1 MHz) | 80-100 (1 MHz) | 100 (10 MHz) | μ | 10,000 (10 kHz) |
| ε (1 MHz) | 12 | 18 | 20 | ε | (metal) |
| 4πMₛ (G) | 1,740 | 3,200 | 5,500 | 4πMₛ(G) | 14,000 |

(ρ (Ω-cm) resistivity, μ permeability, ε (1 MHz) permittivity, 4πMₛ (G) saturation magnetization).

### Magnetic Insulator Particles

Ferrites offer tremendous insulating and ultra-low damping properties at a sacrifice to permeability and saturation induction (i.e., magnetization). In contrast, ferromagnetic metallic glasses possess exceptionally high permeability and saturation induction, but become lossy at frequencies beyond ˜10's of KHz. A carefully engineered composite of the two components can result in an optimal compromise where the best of both materials can be realized for high frequency applications. Making such a composite is disclosed in more detail below.

The role of the ferrite particles can include: 1) Substantially increasing the high frequency effective saturation magnetization and permeability by strengthening the intergranular dipolar interactions between ferromagnetic metal and ferrite grains. 2) Suppressing induced eddy currents by substantially increasing the resistivity of the current path and therefore reducing the heat dissipation of the components via their highly resistive (˜10¹² Ohm-cm) ferrite particle or flakes. 3) Shifting the influence of space charge, i.e., Maxwell-Wagner polarization, and the subsequent displacement current to higher frequency to extend the range of the inductors' operational frequency. This is, in essence, engineering the dispersion of dielectric properties of the ferromagnetic metal-ferrite interfaces of the nanocomposites disclosed herein. 4) Adjusting the cutoff frequency of the ferromagnetic metal-ferrite nanocomposite to capture a wider spectral range of power density by increasing the AC resistivity and spin resonance frequency of the composite. In principle the limiting upper end of the frequency range is a frequency corresponding to domain wall and gyromagnetic resonances, at which frequency the composites become too lossy to serve as efficient inductors or transformers, power converters, power inverters, filters, etc. At higher frequency devices would experience losses and generate heat.

The present technology serves to suppress eddy current losses and retain long-range magnetic continuity and permeability. In a preferred embodiment, the approach entails the introduction of electrically insulating ferrite particles as a coating or as an inter-particulate constituent relative to the ferromagnetic metallic constituent.

Regarding the ferrite size and shape properties, the optimal particle size of the ferrite varies with the type and chemistry of the magnetic insulating particle. In an example, the particle size range is in a range from about 5 nm to about 100 micrometers. The aspect ratios (AR) range from spheroidal (AR from about 1:1 to about 10:1) to platelet-shaped (AR from about 10:1 to about 200:1) to much higher (from about 200:1 to essentially infinite) in the case of long fibers. Fibers can have a diameter from about 30 micrometers to about 500 micrometers and lengths from about 1 millimeter to about 1 cm, or to about 1 meter, or to about 100 meters or longer and be continuous or semi-continuous (i.e., having occasional break in the fiber strand). Fibers also can be provided as bundles of a plurality of laterally associated fibers, or as spooled fibers or bundles of fibers. Fibers can have an aspect ratio of up to about 1000000:1 or greater, such as 10000000:1 or even 100000000:1. The only limitation to fiber length is the practicality of manufacture.

### Ferromagnetic Metallic Particles

Ferromagnetic metallic particles (FMPs) can take the form of high permeability, high magnetic moment alloys that may be crystalline (FeSi-based, FeNi-based, FeCo-based, etc.), nanocrystalline (similar to nanoperm or finemet and related alloys, e.g., FeCoNiNbCuSiB) or glassy in structure (amorphous, similar to the Metglas™ products, e.g., FeCoNiBSiP). The optimal particle size and shape varies with the type and chemistry of the FMPs. In an example, particle sizes may be in a range from about 50 nm-to about 500 micrometers. The aspect ratios (AR) range from spheroidal (AR from about 1:1 to about 10:1) to platelet-shaped (AR from about 10:1 to about 200:1) to much higher (from about 200:1 to essentially infinite) in the case of long fibers. Fibers can have a diameter from about 30 micrometers to about 500 micrometers and lengths from about 1 millimeter to about 1 cm, or to about 1 meter, or to about 100 meters or longer and be continuous or semi-continuous (i.e., having occasional break in the fiber strand). Fibers also can be provided as bundles of a plurality of laterally associated fibers, or as spooled fibers or bundles of fibers. Fibers can have an aspect ratio of up to about 1000000:1 or greater, such as 10000000:1 or even 100000000:1. The only limitation to fiber length is the practicality of manufacture.

### Dielectric and Binder Materials

Table 2 lists nonlimiting examples of suitable dielectric and binder materials for use with the present technology.

TABLE 2

| | | Elec Loss | Frequency |
|---|---|---|---|
| Material | Permittivity ε' | tangent | Range |
| Cycloaliphatic Epoxy | 3.2 | <0.017 | 1-1000 MHz |
| Bisphenol-A Epoxy | 3.7 | <0.015 | 1-1000 MHz |
| Vinyl Ester Resin | 3.4 | <0.016 | 1-100 MHz |
| PTFE Thermoplastic | 2.2 | <0.0004 | Wide Band |
| Phenolic Plastics | 5.2 | <0.025 | @1 MHz |
| Polyester thermoplastic | 3.2 | <0.005 | Wide Band |
| Epoxy resin D.E.R. 331 | 3.2 | <0.022 | 1-1000 MHz |
| Rogers Thermoset | 3.5 | <0.0025 | Up to 10 GHz |
| Laminates | | | |

### Fabrication and Characterization

FIG. 4B shows a flow diagram of a process used to fabricate materials according to the present technology; the characterization of such materials is described below.

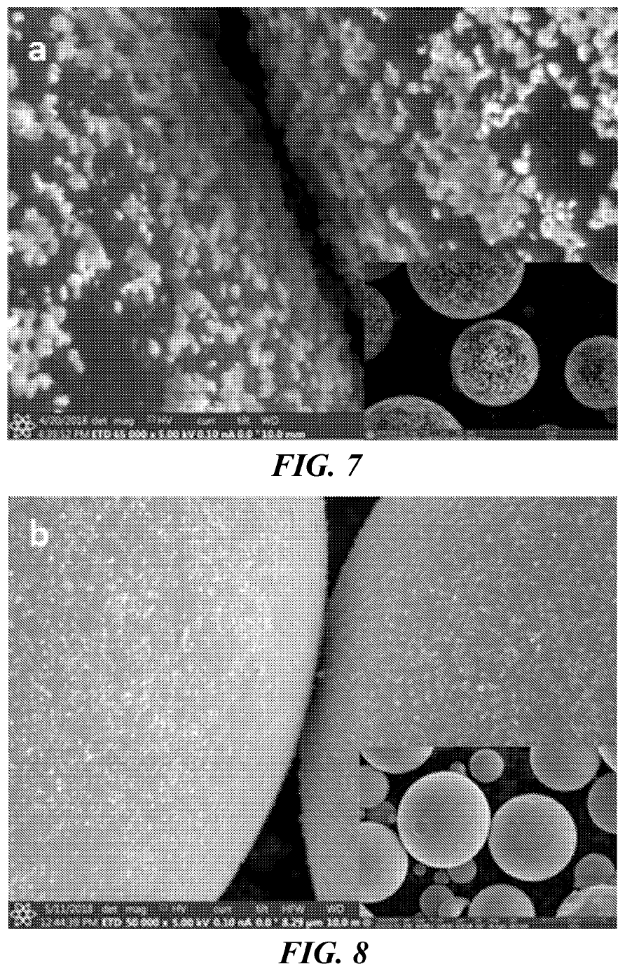

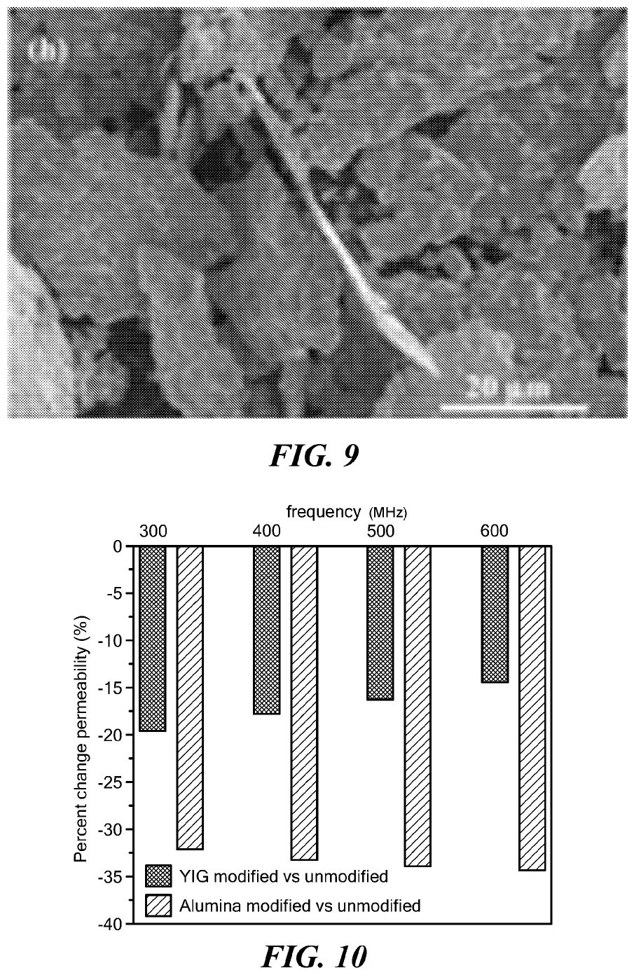

FIGS. 7-8 show SEM images of surface coverage of insulating ferrite particles decorating FMPs. In these examples, the FMPs are quasi-spherical (i.e., roughly spherical but faceted), but there is evidence that flake-like particles of high aspect ratio can provide superior properties (e.g., high permeability). Flake-like particles, as shown in FIG. 9 can be, for example, made by mechanical deformation using a ball mill.

The coverage of the magnetic insulating ferrite particles on the FMPs (or the FMPs on the ferrites) need not be total nor continuous, that is, it can be partial or in essence decorate the surface of the metallic particles as is shown clearly in FIG. 7 and in FIGS. 1-3.

In the embodiment wherein ferrite particles are utilized to coat ferromagnetic metallic particles, some fraction of the ferrite particles can be suspended in a binder between the FMPs (FIG. 4A). This approach also can be used for the case when the FMPs serve to coat the ferrite particles and are suspended between the ferrite particles to enhance the permeability and magnetization (e.g., FIGS. 1-3).

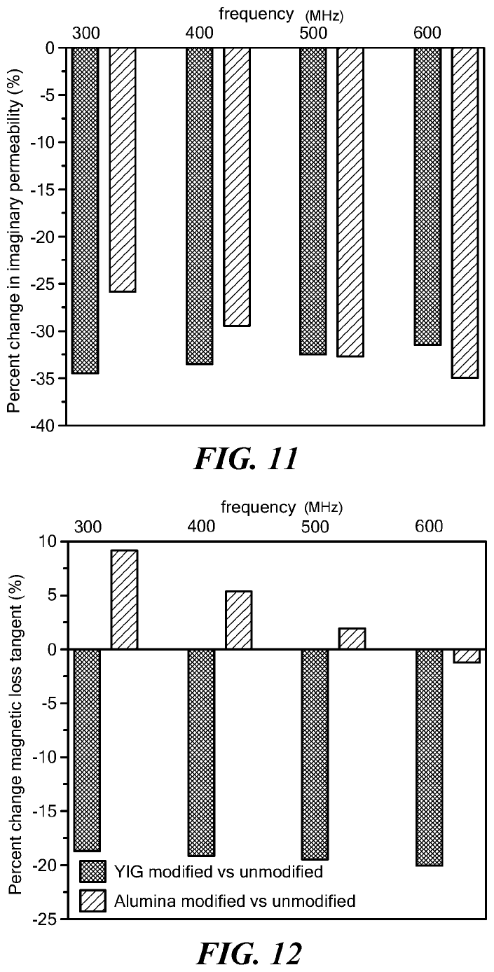

A proof-of-concept study including YIG particles coated on FMPs, and suspended between FMPs, is conducted. In this study, YIG additives are found to not only substantially reduce total power loss attributable to the eddy current loss component, but also sustain a high permeability and magnetization. This is in comparison to control samples that are modified by the addition of alumina particles, which did not reduce loss tangents appreciably due to the detrimental impact on permeability and lessor suppression of eddy currents. In this study, FIGS. 10-12 illustrate percent change permeability (FIG. 10), percent change in imaginary permeability (FIG. 11), and percent change in loss tangent (FIG. 12) for YIG and for alumina coated metallic (FMP) particles as a function of frequency.

The data presented in FIGS. 10-12 confirm the significant difference in the percent change of permeability caused by the introduction of insulating additives. As can be seen in FIG. 11, at 500 MHz, where the addition of both magnetic and nonmagnetic additives results in the similar reduction in μ″ of ˜32% (a direct reflection of loss), the addition of the magnetic YIG additive results in less than ˜17% reduction in permeability compared to the ˜35% reduction caused by the alumina additive (shown in FIG. 10). As a result, at 500 MHz, the addition of YIG improves (i.e., reduces) the magnetic loss tangent by ˜20% in comparison with the negative impact of the nonmagnetic alumina additive (FIG. 12). Note, the magnetic loss tangent is a principle performance metric for power inductor magnetic materials.

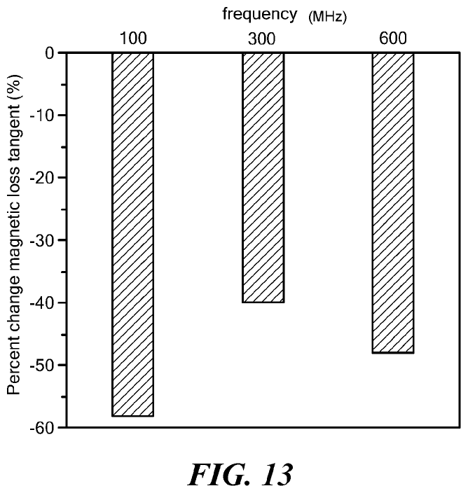

Similarly, a significant improvement of ˜40-60% decrease in magnetic loss tangent is measured in flake-based FMPs upon the introduction of YIG additives when the flakes are suspended in a binder. This is depicted in FIG. 13, which shows Percent change magnetic loss tangent for YIG coated metallic flakes as a function of frequency.

The results presented in FIGS. 10-13 can, through engineering of soft magnetic composites (SMCs), be explained in greater detail. To further explore the technology, novel metal-ceramic nanocomposites are prepared by cold sintering for the first time. As a model system, Fe-based nanocrystalline alloys with NiZn ferrites and α-Fe₂O₃ ceramics are cold sintered at 150° C. under a uniaxial pressure of 320 MPa. These nanocomposites illustrate dense microstructures, fine grains, and high electrical resistivities, allowing remarkable high-frequency performance, such as permeability values of about 11.5 at frequencies up to about 1 GHz, with corresponding quality factors reaching over 100 at tens of megahertz.

### General Features

Power inductors using the developed composite materials demonstrate low DC resistance (18.35 mW), high efficiency (≈98.2%), and high current rating with small form factors far superior to those available as commercial products. This represents a dramatic advance in the materials science and development of inductor composite materials for power electronics applications.

Communication networks, including advances in 5G and 6G wireless networks, have developed towards greater transmission rates with lower latency, higher network capacity and connectivity, smaller terminal device size, higher power, and energy efficiency with enhanced reliability. This sets a high standard for the performance of essential components and their materials, for instance, soft magnetic materials used in power inductors. Prior to the disclosure herein, the existing soft magnetic materials suffer from low power storage capacities, poor stability, low permeabilities, and high losses with increasing operating frequencies and power densities. The need for high-performance soft magnetic materials to address the demands of next-generation power electronics requires great urgency.

The present technology offers several novel and useful features, including the following. 1) Use of ferrites in combination with ferromagnetic metallic particles in which ferrites represent a very small weight fraction. 2) Use of ferrites in combination with ferromagnetic metallic particles in which ferrites are nanoparticles. 3) Use of ferrites in combination with ferromagnetic metallic particles in which ferrites may be micron sized particles. 4) Use of ferrite particles in which ferrites may be spheroids or flakes of aspect ratios from 1:1 to 200:1, or higher in the case of long fibers. 5) Use of ferrites in combination with metallic particles in which ferrites provide a decorative coating to the ferromagnetic metallic particles. 6) Use of ferrites in combination with ferromagnetic metallic particles in which ferrites reside between ferromagnetic metallic particles as may be the case when particles are suspended in a host dielectric or binder material. 7) Use of ferromagnetic metallic particles in which particles may be spheroids or flakes of aspect ratios from 1:1 to 200:1, or higher in the case of long fibers. 8) Ferromagnetic metallic particles (FMPs) and ferrite particles may be suspended within a host dielectric or binder material.

The present technology offers advantages and improvements over existing methods, devices, or materials, including the following. Very small amounts of insulating magnetic particle (i.e., ferrite particles), as low as <0.2 wt. % (of the metallic constituent), are able to suppress core losses (as much as 80%) when used as a coating on ferromagnetic metallic particles or as an inter-particulate constituent. Magnetic loss tangents at frequencies from 10 kHz to 500 MHz and above are reduced considerably. The use of alumina as a similarly prepared control sample was found to increase loss tangent (FIG. 12), attributed to the detrimental impact on permeability by alumina. Permeability is maintained at high levels compared to other nonmagnetic insulating additives due to the maintained long-range magnetic interactions. Small form factors are realized related to sustained high saturation magnetization. As much as a 50% reduction in magnetic loss tangent is achieved at 500 MHz when ferrites are added to FMP flakes or platelets suspended in a binder (FIG. 13). Very small amounts of ferromagnetic metallic particles used as a coating on ferrite particles or as an inter-particulate constituent are able to enhance permeability and magnetization of the composite significantly as a function of the ratio of the two constituents.

Examples of commercial applications of the present technology include the following. The materials can be used in power generation, conversion, and conditioning at frequencies above 10 kHz to beyond 1 GHz. The materials also can be used in inductors, transformers, power inverters/converters, filters, and power supplies. Devices using the materials have small form factors. The materials offer reduction in power consumption as low loss inductor cores in switch mode power supplies.

An apparatus including the composite materials can be, for example, a ferrite toroid, a ferrite plate, a ferrite disk, a ferrite C shaped core, a planar E core, an E/I core, a gaped toroid, and a bobbin core. The apparatus can be a device with a core component including the composite materials, and the device can be, for example, an EMI suppressor, an absorber, a transformer, an electronic device, an inductor, a power converter, a transmit and receive module (TRM), an Electronically Scanned Phased Arrays (ESPA) system, an Electronic Warfare (EW) system, and a communication device having a switch mode power supply (SMPS) conditioning component. Examples of systems that can include the composite materials are Electronically Scanned Phased Arrays (ESPA) and Electronic Warfare (EW) systems, conditioning components for wireless and satellite communication, radar systems, power electronics, inductive devices and systems, and devices or electronics utilizing 3 switched-mode power supplies.

The composites can be produced in a mixture. Forming the mixture can include combining the first component with the second component or combining the second component with the first component. The mixture can optionally be dried and/or separated according to particle size, for example, by sieving. The mixture can optionally include a binder. The mixture can be formed into any desired shape. The steps of forming the mixture, drying the mixture, and separating the mixture according to particle size can be in any order. The mixture can be formed into a green body. The green body can be sintered. The green body can be heated prior to sintering the green body. The green body can be shaped as a core component. For example, the core component can be a ferrite toroid, a ferrite plate, a ferrite disk, a ferrite E-core, or a ferrite El-core. A device can be provided and the green body can be disposed in the device. Examples of devices are a transformer, a suppressor, an inductor, a power converter, an absorber, a transmit and receive module (TRM), an Electronically Scanned Phased Arrays (ESPA) system, an Electronic Warfare (EW) system, and a communication device having a SMPS conditioning component.

### EXAMPLES

### Example 1. Comparison of Alumina Particles and Magnetic YIG Additives to FMPs

A control sample of FMPs was modified by the addition of alumina particles. A separate sample of FMPs was modified by the addition of YIG particles. The percent change in permeability for the alumina modified FMPs and for the YIG modified FMPs is plotted in FIG. 10 as a function of frequency. The percent change in imaginary permeability (μ″) is compared in FIG. 11. The percent change loss tangent for the YIG and alumina coated metallic particles is compared as a function of frequency in FIG. 12.

In FIG. 11, at 500 MHz, where the addition of both magnetic and nonmagnetic additives resulted in the similar reduction in μ″ of ˜32% (a direct reflection of loss), the addition of the magnetic YIG additive resulted in less than ˜17% reduction in permeability (FIG. 10, 500 MHz) compared to the ˜35% reduction caused by the alumina additive. As a result, in FIG. 12 at 500 MHz, the addition of YIG improved (i.e., reduced) the magnetic loss tangent by ˜20% in comparison with the negative impact of the nonmagnetic alumina additive. The magnetic loss tangent is a principle performance metric for power inductor magnetic materials.

### Example 2. Addition of YIG Additives to Flake-Based FMPs

A significant improvement of ˜40-60% decrease in magnetic loss tangent was measured in flake-based FMPs upon the introduction of YIG additives when the flakes were suspended in a binder. This is depicted in FIG. 13, which shows the percent change magnetic loss tangent for YIG coated metallic flakes as a function of frequency.

### Example 3. Fabrication of Composite Containing NiZn-Ferrite Nanoparticles on and Suspended Between Ferromagnetic Platelets Containing FeCuNbSiB

A second proof-of-concept was demonstrated and is published as T Zhou, Y Liu, P Cao, J Du, Z Lin, R Wang, L Jin, L Lian, and VG Harris, “Cold Sintered Metal-Ceramic Nanocomposites for High-Frequency Inductors,” Advanced Electronic Materials, 6 (12), 2000868 (2020). This demonstration explored a composite consisting of a ferromagnetic metallic alloy, FeCuNbSiB (a composition of Fe_{73.5}Cu₁Nb₃Si_{13.5}B₉) particles, with various amounts of NiZn-ferrite particles serving as the highly resistive magnetic coating.

The composites were prepared as follows:

### Step 1: Formation of the Ferromagnetic Metallic Powder

FeCuNbSiB alloy powders with nominal molar percentages of 1% Cu, 3% Nb, 13.5% Si, 9% B and Fe for balance, were melted and homogenized, pulverized, and sieved to a particle size ranging from ≈5 to ≈45 μm.

### Step 2: Formation of the High-Resistivity Coating on Metallic Particles

NiCl₂.6H2O, ZnCl₂, and FeCl₃, with a molar ratio set to 0.5:0.5:2, were used as raw materials for the coating. These metal-chlorides were dissolved in 65° C. deionized water (500 mL), in which citric acid was added. The molar ratio of citric acid to Ni²⁺, Zn²⁺, and Fe³⁺ cations was set to 1:1.5, 1:2, and 1:1, respectively.

Thereafter, predetermined amount of FeCuNbSiB alloy powders (as particles) was added to the aqueous solution and stirred at 300 rpm under ultrasonic stimulation for 1 min.

All raw materials were weighed according to the composition of FeCuNbSiB+x wt % Ni_{0.5}Zn_{0.5}Fe₂O₄ where x=0.5, 1.0, 2.0, 3.0, 4.0, 5.0, and 6.0.

Subsequently, ammonia solutions were added dropwise until the solution pH of 9.5 was reached.

During the treatment, the mixtures were continuously stirred at 300 rpm under ultrasonic stimulation for 30 min at 65° C. to expose each particle in the solution to ensure uniform coating on the surface of the alloy particles.

Thereafter, the mixtures were aged at room temperature for 1 day to form a sol on the alloy particles' surface. The composite powders were then cleaned in deionized water and dried at 80° C. for 6 h to form a gel-like coating on the alloy particles.

FeCuNbSiB@gel powders where confirmed by X-ray diffraction to consist of FeCuNbSiB alloy particles and a ferrite phase.

### Step 3: Preparation of High Density Soft Magnetic Composite Toroids

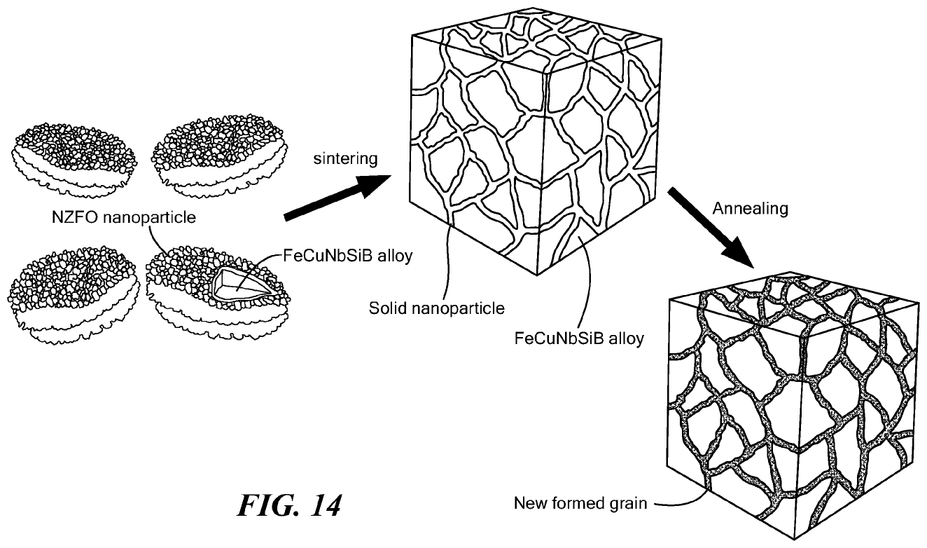

Samples were prepared and treated according to ceramic methodologies (see FIG. 14) to obtain high density toroidal samples. Toroids were used to measure complex permeability, i.e., real part (μ′) and imaginary part (μ″), over megahertz to gigahertz frequencies.

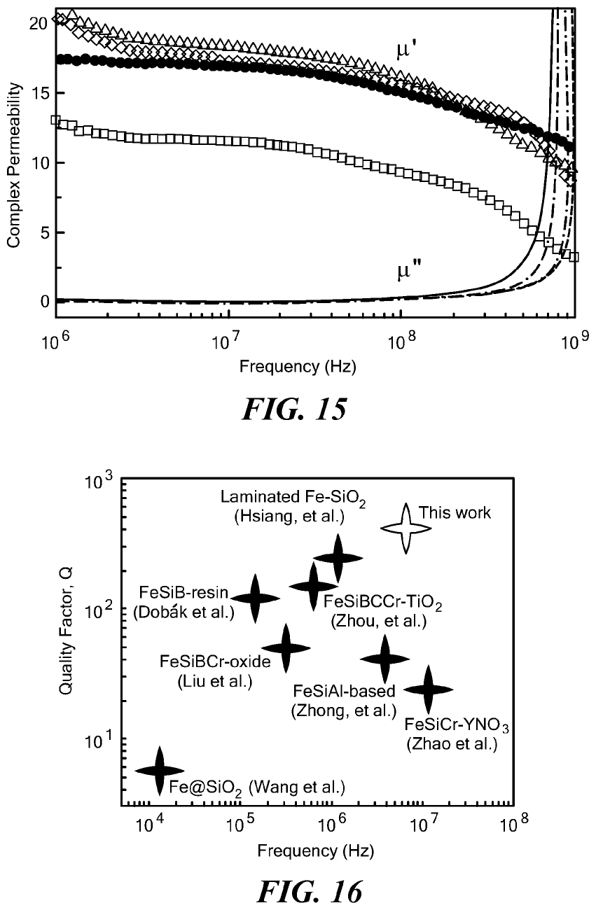

For x=1.0 wt % of high resistive NiZn-ferrite particles, samples possess excellent high-frequency performance that show the lowest μ″ values (i.e., μ″≈0.10 at 50 MHz) and the highest frequency μ′≈11.5 to ≈950 MHz (see FIG. 15).

The resulting Q factor is plotted in FIG. 16 where it compares favorably against other technologies. This result validates its high-frequency performance and soft magnetic properties that provide it tremendous potential for applications in high-frequency inductors, power converters, transformers, and power management ICs.

### REFERENCES

B. Zhou, Y. Dong, L. Liu, L. Chang, F. Bi, X. Wang, J. Magn. Magn. Mater. 2019, 474, 1.
X. Zhong, Y. Liu, J. Li, Y. Wang, J. Magn. Magn. Mater. 2012, 324, 2631.
H.-I. Hsiang, L.-F. Fan, J.-J. Hung, J. Magn. Magn. Mater. 2018, 447, 1.
S. Dobák, J. Füzer, P. Kollár, M. Strečková, R. Bureš, M. Fáberová, J. Alloys Compd. 2017, 695, 1998.
J. Wang, X. Fan, Z. Wu, G. Li, J. Mater. Sci. 2017, 52, 7091.
Y. Liu, Y. Yi, W. Shao, Y. Shao, J. Magn. Magn. Mater. 2013, 330, 119.
J. Zhao, C. Wu, D. Luo, M. Yan, J. Magn. Magn. Mater. 2019, 481, 140.

What is claimed is:

1. A composite material comprising (i) ferromagnetic metallic particles, (ii) resistive magnetic particles, and optionally (iii) a dielectric material or binder in which the particles of (i) and (ii) are embedded; wherein either (i) or (ii) is present in the form of core particles and the other of (i) and (ii) is present in the form of coating particles which at least in part coat the core particles.

2. The composite material of claim 1, wherein the core particles comprise said ferromagnetic metallic particles and the coating particles comprise said resistive magnetic particles.

3. The composite material of claim 1, wherein the core particles comprise said resistive magnetic particles and the coating particles comprise said ferromagnetic metallic particles.

4. The composite material of claim 1, wherein a first portion of the coating particles is bound to the core particles and a second portion of the coating particles is embedded in the dielectric material.

5. The composite material of claim 1, wherein essentially all of the coating particles are bound to the core particles.

6. The composite material of claim 1, wherein the core particles have a form selected from spheroids, platelets, and fibers, the spheroids having an aspect ratio (longest dimension to thickness) from about 1:1 to about 10:1, the platelets having an aspect ratio from about 10:1 to about 200:1, and the fibers having an aspect ratio from about 200:1 to about 1000000:1 or greater.

7. The composite material of claim 1, wherein the core particles have an average particle size from about 50 nm to about 500 micrometers.

8. The composite material of claim 1, wherein the coating particles have an average particle size from about 5 nm to about 100 micrometers.

9. The composite material of claim 1, wherein the ferromagnetic metallic particles have an electrical resistivity from about 20 microOhm-cm to about 500 microOhm-cm.

10. The composite material of claim 1, wherein the resistive magnetic particles have an electrical resistivity from about 10⁸ Ohm-cm to about 10¹² Ohm-cm.

11. The composite material of claim 1, wherein the ferromagnetic metallic particles comprise a material selected from the group consisting of FeSi silicon steels, FeNi permalloy steels, FeCo permendur steels, (Fe and/or Co and/or Ni)(B and/or Si and/or Zr)(Cu and/or Nb) nanocrystalline alloys, (Fe and/or Co and/or Ni)(B and/or Si and/or P) metallic glasses, and combinations thereof.

12. The composite material of claim 1, wherein the resistive magnetic particles comprise a material selected from the group consisting of: (i) spinel ferrites of formula [Me₁,Me₂]ₓFe₂₋ₓO₄, wherein Me₁ and Me₂ are selected from Ni, Mn, Zn, Cu, Fe, Co, Mg, Cr, and combinations thereof; (ii) garnet ferrites of formula [Y(Me₁)]₃Fe₅O₁₂, wherein Me₁ is selected from elements of the lanthanide series; and (iii) hexaferrite phases of the M-type [BaMe₁](FeMe₂)₁₂O₁₉, wherein Me₁ is selected from Sr, Mo, Ir, Hf, and elements of the lanthanide series, and Me₂ is selected from Co, Ni, Zn, Ti, Zr, Al, Ga, Sn, and combinations thereof.

13. The composite material of claim 1, wherein the resistive magnetic particles comprise a crystal structure selected from the group consisting of spinel-type, garnet-type, hexaferrite-type, and combinations thereof.

14. The composite material of claim 1, wherein the coating particles are present in an amount of greater than 0.01 wt-% and less than 2 wt-% based on the weight of the core particles as 100%.

15. The composite material of claim 1, wherein the material comprises said dielectric material or said binder.

16. The composite material of claim 1, wherein the material provides a reduction in core loss of at least about 60%, at least about 70%, or at least about 80% compared to a conventional ferromagnetic core when used in an inductor at any frequency from 10 kHz to 5 MHz, or from 10 kHz to 10 MHz, or from 10 kHz to 50 MHz, or from 10 kHz to 100 MHz.

17. An electronic device or component comprising the composite material of claim 1.

18. Use of the composite material of claim 1 in a device selected from the group consisting of a transformer, an electronic device, an inductor, a power supply, a power inverter, a power converter, an inductor, a transmit and receive module, an electronically scanned phased array system, an electronic warfare system, an EMI suppressor or absorber, and a communication device having a switch-mode power supply conditioning component.

19. A method of fabricating a composite material, the material comprising a plurality of core particles, each core particle coated with a plurality of coating particles, the method comprising the steps of:
(a) providing a plurality of core particles and a plurality of coating particles, wherein the core particles comprise ferromagnetic metallic particles and the coating particle-s comprise resistive magnetic particles, or wherein the core particles comprise ferromagnetic metallic particles and the coating particles comprise ferromagnetic metallic particles;
(b) mixing said core particles and said coating particles;
(c) heating and applying pressure to the mixture from (b) to consolidate and densify the particles; and optionally
(d) annealing the product of (c).

20. The method of claim 19, further comprising forming the mixture from (b) into a desired shape prior to or during (c).

21. The method of claim 19, wherein the core particles have a form selected from spheroids, platelets, and fibers, the spheroids having an aspect ratio (longest dimension to thickness) from about 1:1 to about 10:1, the platelets having an aspect ratio from about 10:1 to about 200:1, and the fibers having an aspect ratio from about 200:1 to about 1000000:1 or greater.

22. The method of claim 21, wherein the provided core particles are spheroids and the method further comprises deforming the core particles to increase their aspect ratio to a range from about 10:1 to about 200:1.

23. The method of claim 22, wherein the deforming comprises subjecting the provided core particles to ball milling.

24. The method of claim 19, wherein the core particles have an average particle size from about 50 nm to about 500 micrometers.

25. The method of claim 19, wherein the coating particles have an average particle size from about 5 nm to about 100 micrometers.

26. The method of claim 19, wherein the ferromagnetic metallic particles have an electrical resistivity from about 20 microOhm-cm to about 500 microOhm-cm.

27. The method of claim 19, wherein the resistive magnetic particles have an electrical resistivity from about 10⁸ Ohm-cm to about 10¹² Ohm-cm.

28. The method of claim 19, wherein the ferromagnetic metallic particles comprise a material selected from the group consisting of FeSi silicon steels, FeNi permalloy steels, FeCo permendur steels, (Fe and/or Co and/or Ni)(B and/or Si and/or Zr)(Cu and/or Nb) nanocrystalline alloys, (Fe and/or Co and/or Ni)(B and/or Si and/or P) metallic glasses, and combinations thereof.

29. The method of claim 19, wherein the resistive magnetic particles comprise a material selected from the group consisting of: (i) spinel ferrites of formula [Me₁,Me₂]ₓFe₂₋ₓO₄, wherein Me₁ and Me₂ are selected from Ni, Mn, Zn, Cu, Fe, Co, Mg, Cr, and combinations thereof; (ii) garnet ferrites of formula [Y(Me₁)]₃Fe₅O₁₂, wherein Me₁ is selected from elements of the lanthanide series; and (iii) hexaferrite phases of the M-type [BaMe₁](FeMe₂)₁₂O₁₉, wherein Me₁ is selected from Sr, Mo, Ir, Hf, and elements of the lanthanide series, and Me₂ is selected from Co, Ni, Zn, Ti, Zr, Al, Ga, Sn, and combinations thereof.

30. The method of claim 19, wherein the resistive magnetic particles comprise a crystal structure selected from the group consisting of spinel-type, garnet-type, hexaferrite-type, and combinations thereof.

31. The method of claim 19, wherein the coating particles are present in an amount of greater than 0.01 wt-% and less than 2 wt-% based on the weight of the core particles as 100%.

32. The method of claim 19, wherein in the formed composite material the coating particles cover from 10 to 100 percent of the surface of the core particles.

33. The method of claim 19, further comprising providing a dielectric material or binder material in (a) and mixing the dielectric or binder material with the core particles and coating particles in (b).

34. The method of claim 33, wherein in the formed composite material the dielectric material or binder material fills gaps between coated core particles, and wherein the dielectric material or binder material comprises unbound coating particles.

35. The method of claim 33, wherein in the formed composite material the dielectric material or binder material fills gaps between coated core particles, and wherein the dielectric material or binder material is essentially devoid of unbound coating particles.

36. A composite material fabricated by the method of claim 19.

37. An electronic device comprising the composite material of claim 36.
